(19) United States
(12) Patent Application Publication
(10) Pub. No.: US 2026/0299439 A1
(43) Pub. Date: Oct. 1, 2026

(54) STAGE MECHANISM, CHARGED PARTICLE BEAM IRRADIATION APPARATUS, AND CHARGED PARTICLE BEAM IRRADIATION METHOD

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/563,544

(22) Filed: Mar. 11, 2026

(30) Foreign Application Priority Data
Mar. 27, 2025 (JP) 2025-054497

(51) Int. Cl. G03F 7/00

(52) U.S. Cl. CPC G03F 7/70716; G03F 7/704; G03F 7/70791

(57) ABSTRACT

According to one aspect of the present invention, a stage mechanism includes four or more support members configured to include a first support member whose upper end is arranged at a first height, and a second support member whose upper end is arranged at a second height lower than the first height, wherein any one of the plurality of substrates is supported by either one of by respective upper ends of support members of a first group which is composed of three or more support members including the first support member in the four or more support members, and by respective upper ends of support members of a second group which is composed of three or more support members including the second support member in the four or more support members.

### CROSS-REFERENCE TO RELATED APPLICATION

This application is based upon and claims the benefit of priority from prior Japanese Patent Application No. 2025-054497 filed on Mar. 27, 2025 in Japan, the entire contents of which are incorporated herein by reference.

### BACKGROUND OF THE INVENTION

### Field of the Invention

Embodiments of the present invention relate to a stage mechanism, a charged particle beam irradiation apparatus, and a charged particle beam irradiation method, and, for example, relate to a stage mechanism mounted on a writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared with writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

Conventionally, a 6×6 inch mask has been used for a long time as a target object to be written. Therefore, the writing apparatus for writing patterns on the mask is configured so that the 6×6 inch mask can be placed.

In High-NA EUV (extreme ultraviolet) exposure processing, since an anamorphic optical system is used, two 6-inch masks obtained by dividing the full field up and down are exposed. In contrast, there is examined a method in which the full field is exposed by using one large 6×12 inch mask. Accordingly, the writing apparatus is needed to be able to write with respect to both the 6×6 inch mask and the large 6×12 inch mask. Thus, the writing apparatus where target objects of different sizes can be placed is requested. This matter is applied not only to the writing apparatus but also to other apparatuses.

While not being related to the stage of the writing apparatus, there is disclosed a method where a plurality of support pins which can treat with substrates of various dimensions are arranged for a robot hand for transmitting a mask (refer to Japanese Patent Application Laid-open (JP-A) No. 10-55944).

### BRIEF SUMMARY OF THE INVENTION

According to one aspect of the present invention, a stage mechanism includes
a stage configured to be movable; and
four or more support members configured to include a first support member whose upper end is arranged at a first height, and a second support member whose upper end is arranged at a second height lower than the first height, to be arranged such that height positions of upper ends of the four or more support members are between at least the second height and at most the first height, where the first height and the second height are included, and to be fixed on the stage, wherein
the stage mechanism can individually selectively support a plurality of substrates having different sizes, and
any one of the plurality of substrates is supported by either one of by respective upper ends of support members of a first group which is composed of three or more support members including the first support member in the four or more support members, and by respective upper ends of support members of a second group which is composed of three or more support members including the second support member in the four or more support members.

[2] According to another aspect of the present invention, a charged particle beam irradiation apparatus includes
a stage mechanism configured to include
   a stage which is movable, and
   four or more support members which include a first support member whose upper end is arranged at a first height, and a second support member whose upper end is arranged at a second height lower than the first height, which are arranged such that height positions of upper ends of the four or more support members are between at least the second height and at most the first height, where the first height and the second height are included, and which are fixed on the stage, wherein
   the stage mechanism can individually selectively support a plurality of substrates having different sizes, and
   any one of the plurality of substrates is supported by either one of by respective upper ends of support members of a first group which is composed of three or more support members including the first support member in the four or more support members, and by respective upper ends of support members of a second group which is composed of three or more support members including the second support member in the four or more support members; and
an irradiation mechanism configured to irradiate the any one of the plurality of substrates supported with a charged particle beam.

According to yet another aspect of the present invention, a charged particle beam irradiation method includes
placing any one of a plurality of substrates, by using a charged particle beam irradiation apparatus that includes a stage mechanism which includes a stage being movable, and four or more support members where a first support member whose upper end is arranged at a first height and a second support member whose upper end is arranged at a second height lower than the first height, wherein the four or more support members are arranged such that height positions of upper ends of the four or more support members are between at least the second height and at most the first height, including the first height and the second height, and are fixed on the stage, wherein the stage mechanism can individually selectively support a plurality of substrates having different sizes, on either one of on respective upper ends of support members of a first group which is composed of three or more support members including the first support member in the four or more support members, and on respective upper ends of support members of a second group which is composed of three or more support members including the second support member in the four or more support members; and
irradiating the any one of the plurality of substrates placed with a charged particle beam.

### BRIEF DESCRIPTION OF THE DRAWINGS

FIG. 1 is a schematic diagram showing a configuration of a writing apparatus according to a first embodiment;

FIG. 2 is a top view showing an example of arrangement position of a plurality kinds of target objects arranged on a stage mechanism according to the first embodiment;

FIG. 3 is a front view showing an example of a configuration of a stage mechanism in the state where an example of a target object is placed on the stage mechanism according to the first embodiment;

FIG. 4 is a front view showing an example of a configuration of a stage mechanism in the state where another example of a target object is placed on the stage mechanism according to the first embodiment;

FIG. 5 is an illustration showing an example of a configuration of a support member according to the first embodiment;

FIG. 6 is a conceptual diagram showing a configuration of a shaping aperture array substrate according to the first embodiment;

FIG. 7 is a sectional view showing a configuration of a blanking aperture array mechanism according to the first embodiment;

FIG. 8 is a flowchart showing an example of main steps of a writing method according to the first embodiment;

FIG. 9 is a conceptual diagram for explaining an example of a writing operation according to the first embodiment;

FIG. 10 is an illustration showing an example of an irradiation region of multiple beams and a pixel to be written according to the first embodiment;

FIG. 11 is a top view showing an example of arrangement position of a plurality kinds of target objects arranged on a stage mechanism according to a second embodiment;

FIG. 12 is a front view showing an example of a configuration of a stage mechanism in the state where an example of a target object is placed on the stage mechanism according to the second embodiment;

FIG. 13 is a front view showing an example of a configuration of a stage mechanism in the state where another example of a target object is placed on the stage mechanism according to the second embodiment;

FIG. 14 is a top view showing an example of arrangement position of a plurality kinds of target objects arranged on a stage mechanism according to a third embodiment;

FIG. 15 is a front view showing an example of a configuration of a stage mechanism in the state where an example of a target object is placed on the stage mechanism according to the third embodiment;

FIG. 16 is a front view showing an example of a configuration of a stage mechanism in the state where another example of a target object is placed on the stage mechanism according to the third embodiment;

FIG. 17 is a conceptual diagram showing an example of a configuration of a writing apparatus according to a fourth embodiment;

FIG. 18 is a top view showing an example of arrangement position of a plurality kinds of target objects arranged on a stage mechanism according to the fourth embodiment;

FIG. 19 is a front view showing an example of a configuration of a stage mechanism in the state where an example of a target object is placed on the stage mechanism according to the fourth embodiment;

FIG. 20 is a front view showing an example of a configuration of a stage mechanism in the state where another example of a target object is placed on the stage mechanism according to the fourth embodiment;

FIG. 21 is a flowchart showing an example of main steps of a writing method according to the fourth embodiment;

FIG. 22 is an illustration explaining an example of another usage method of an angle adjustment stage according to the fourth embodiment;

FIG. 23 is a top view showing an example of arrangement position of a plurality kinds of target objects arranged on a stage mechanism according to a fifth embodiment; and

FIG. 24 is a front view showing an example of a configuration of a stage mechanism in the state where an example of a target object is placed on the stage mechanism according to the fifth embodiment.

### DETAILED DESCRIPTION OF THE INVENTION

Embodiments of the present invention provide a stage mechanism and a writing apparatus where target objects of different sizes can be placed.

Embodiments of the present invention describe a configuration using an electron beam as an example of a charged particle beam. The charged particle beam is not limited to the electron beam, and other charged particle beams such as an ion beam may also be used. A configuration which uses multiple electron beams as an example of the charged particle beam is described. However, the charged particle beam is not limited to multiple beams, and a single beam may also be used. Furthermore, an electron beam writing apparatus is described as an example of a charged particle beam irradiation apparatus. The charged particle beam irradiation apparatus is not limited to a writing apparatus, and any apparatus that irradiates a target object placed on a stage with charged particle beams, such as an electron beam inspection apparatus or an electron beam image acquisition apparatus can be used.

### First Embodiment

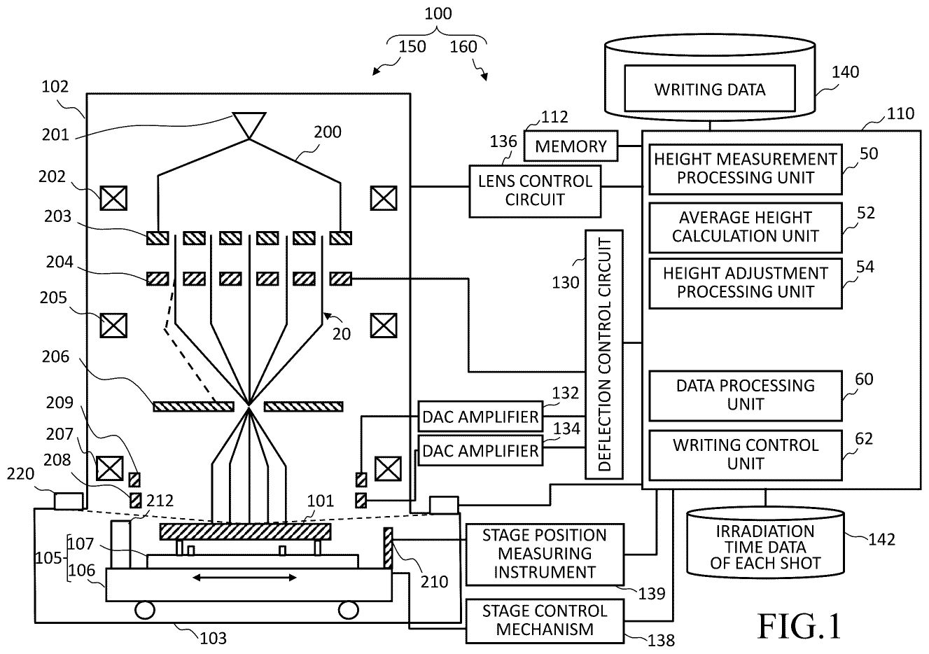

FIG. 1 is a schematic diagram showing a configuration of a writing or “drawing” apparatus according to a first embodiment. As shown in FIG. 1, a writing apparatus 100 includes a writing mechanism 150, a stage mechanism 105, and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, the stage mechanism 105 is disposed. The stage mechanism 105 includes an XY stage 106 which can be moved in the x and y directions, and a Z stage 107 which can be moved in the z direction. The Z stage 107 is arranged on the XY stage 106. A plurality of support members are arranged on the Z stage 107.

On the stage mechanism 105, a target object 101 (300), such as a mask, serving as a writing target substrate, is disposed when writing (exposing) is performed. The target object 101 (300) may be a plurality kinds of substrates having different sizes. For example, the target object 101 (300) may be an exposure mask used in fabricating semiconductor devices, etc. The target object 101 may be a mask blank on which resist has been applied and nothing has yet been written. FIG. 1 shows the case where the target object 101 in the plurality kinds of target objects 101 and 300 having different sizes is placed. The target object 101 is supported from the backside side by at least three or more support members in a plurality of support members.

On the XY stage 106, a mirror 210 for measuring the position of the XY stage 106 is arranged. Furthermore, on the XY stage 106, a mark 212 for checking and/or calibrating a beam position is arranged. On the mark 212, a mark pattern is formed. As the mark pattern, preferably, a cross pattern is used, for example.

On the writing chamber 103, a height position sensor 220 for measuring the height position of the target object 101 (300) is disposed. FIG. 1 shows the case where a z sensor utilizing an optical lever is used as the height position sensor 220. The z sensor includes a laser irradiator which makes a laser beam obliquely enter the target object 101 (300), and a receiving sensor which measures a height position using the principle of optical lever by receiving a reflected light reflected from the target object 101 (300). The height position information measured by the receiving sensor is output to the control computer 110 through a detector (not shown).

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The x-direction position and y-direction position of the XY stage 106 are controlled by a drive of each axis motor (not shown) controlled by the stage control mechanism 138. Based on the principle of laser interferometry, the stage position measurement instrument 139 measures the position of the XY stage 106 by receiving a reflected light from the mirror 210. The z-direction position of the Z stage 107 is controlled by a drive of a motor or a piezoelectric element etc. (not shown) controlled by the stage control mechanism 138.

In the control computer 110, there are arranged a height measurement processing unit 50, an average height calculation unit 52, a height adjustment processing unit 54, a data processing unit 60, and a writing control unit 62. Each of the “ . . . units” such as the height measurement processing unit 50, the average height calculation unit 52, the height adjustment processing unit 54, the data processing unit 60, and the writing control unit 62 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the height measurement processing unit 50, the average height calculation unit 52, the height adjustment processing unit 54, the data processing unit 60, and the writing control unit 62, and information being operated are stored in the memory 112 each time.

Writing operations of the writing apparatus 100 and transmission processing of irradiation time data of each shot to the deflection control circuit 130 are controlled by the writing control unit 62.

Writing data (chip data) is input from the outside of the writing apparatus 100, and stored in the storage device 140. Chip data defines information on a plurality of figure patterns configuring a chip pattern. Specifically, for example, for each figure pattern, coordinates for each vertex are defined in the order of configuration of the figure. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

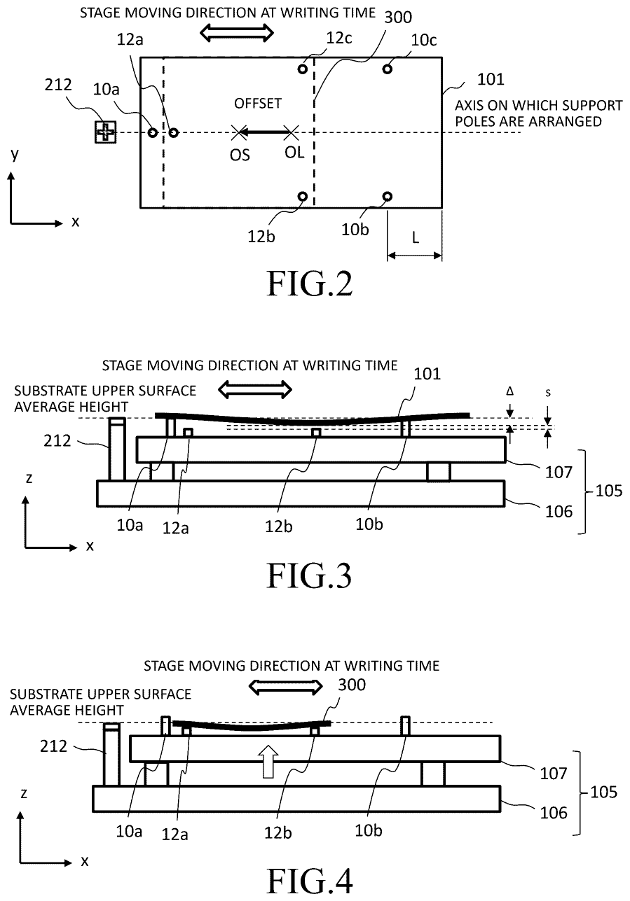

FIG. 2 is a top view showing an example of arrangement position of a plurality kinds of target objects arranged on a stage mechanism according to the first embodiment.

FIG. 3 is a front view showing an example of a configuration of a stage mechanism in the state where an example of a target object is placed on the stage mechanism according to the first embodiment.

FIG. 4 is a front view showing an example of a configuration of a stage mechanism in the state where another example of a target object is placed on the stage mechanism according to the first embodiment.

The stage mechanism 105 according to the first embodiment is configured such that a plurality of mask substrates having different sizes can be individually selectively supported. In the case of FIG. 2, for example, a 6×12 inch mask substrate is used as the target object 101, and a 6×6 inch mask substrate is used as the target object 300. On the Z stage 107, there are arranged, for example, a pole support member 10 (a support pin, the first support member), whose upper end is arranged at a predetermined height position, and a support member 12 (a support pin, the second support member) whose upper end height position is lower than the upper end height position of the support member 10. The height position of the support member, below, indicates a height position of the upper end of the support member in contact with the lower surface of the target object, based on the Z stage upper surface in the case of the Z stage being level, including horizontal. It is not inevitably necessary that the heights of the first and second support members are equal to each other, and thus, they may have a height difference equal to or greater than a tolerance. That is, on the Z stage, there may be arranged the support member 10 whose upper end is arranged on the position equal to or higher than the first height, and the support member 12 whose upper end is arranged on the position equal to or lower than the second height which is lower than the first height position. The support member 10 and the support member 12 are fixed onto the Z stage 107. In other words, the stage mechanism 105 includes four or more support members whose upper ends are arranged to be between at least the second height and at most the first height, where the first height and the second height are included, and which are fixed onto the stage, where the support member 10 whose upper end is arranged at the first height and the support member 12 whose upper end is arranged at the second height lower than the first height are included.

According to the first embodiment, any one of a plurality of substrates is supported by each upper end of support members in a large substrate support member group (the first group) composed of three or more support members including the support member 10 in the four or more support members, or each upper end of support members in a small substrate support member group (the second group) composed of three or more support members including the support member 12 in the four or more support members. In other words, according to the first embodiment, one of a plurality of substrates having different sizes is supported by either each upper end of support members in a large substrate support member group (the first group) composed of three or more support members including at least one support member 10, or each upper end of support members in a small substrate support member group (the second group) composed of three or more support members including at least one support member 12.

FIGS. 2 to 4 show the case where three support members 10 (10a, 10b, 10c) and three support members 12 (12a, 12b, 12c) are arranged.

The large target object 101 is supported by the support members 10a, 10b, and 10c, of which the large substrate support member group (the first group) is composed, in a plurality of support members 10. In the cases of FIGS. 2 to 4, the target object 101 is supported at three points by the three support members 10a, 10b, and 10c in the state where the long side direction of the rectangular target object 101 is set to be in the writing direction (x direction). Each of the support members 10a, 10b, and 10c is disposed close to the end of the target object 101. However, if the x-direction size and the y-direction size of the target object 101 are different from each other, the support member 10a is arranged at the intermediate position of the short side of the target object 101 and close to one end of the long side of the target object 101. The other two support members 10b and 10c are arranged close to the end of the short side of the target object 101 and at the positions inner from the other end of the long side of the target object 101 by a length L. As the length L, ⅓ or less of the length of the long side is set. More preferably, the length L is set to be in the range from ⅓ to ⅕ of the length of the long side of the target object 101. By arranging the three support members 10a, 10b, and 10c at the positions described above, deflection/flexure of the target object 101 at the time of being supported at the three points can be reduced. It is preferable that the first height and the second height are set such that an assumed amount of deflection/flexure of the substrate is larger than a difference between the first height and the second height in order that the upper end may not interfere with the support member of the second height by the deflection/flexure of the substrate supported by the large substrate support member group (the first group).

In the cases of FIGS. 2 to 4, the support member 10a is arranged at the mark 212 side compared with the other two support members 10b and 10c, in terms of the axis in the x direction. However, it is not limited thereto. For example, the support member 10a may be arranged at the opposite side of the mark 212 side compared with the other two support members 10b and 10c, in terms of the axis in the x direction. In other words, the two support members 10b and 10c may be arranged at the mark 212 side compared with the other support member 10a, in terms of the axis in the x direction.

The small target object 300 is supported by the support members 12a, 12b, and 12c, of which the small substrate support member group (the second group) is composed, in a plurality of support members 12. In the cases of FIGS. 2 to 4, the target object 300 is supported at three points. Each of the support members 12a, 12b, and 12c that support the target object 300 whose x-direction size and y-direction size are the same is disposed close to the end of the target object 300. The three support members 12a, 12b, and 12c are arranged within the range between the support member 10a and the support members 10b and 10c with respect to the long side direction (the x direction) of the target object 101. Thereby, it is possible for the three support members 12a, 12b, and 12c not to interfere with the support member 10 when they support the small target object 300.

The Z stage 107 is configured to be movable in two axial directions which are in the same plane. Expressed in another way, the Z stage 107 which moves together with the movement of the XY stage 106 moves regarding the two x and y directions being orthogonal to each other in same plane as moving axes. When performing writing to each stripe region to be described later, the XY stage 106 and the Z stage 107 move while regarding the x direction as a moving axis. Specifically, if the writing direction is the x direction, the stage mechanism 105 moves in the-x direction.

The support members of the large substrate support member group and the support members of the small substrate support member group are arranged such that the center position of the support members of the small substrate support member group (the second group) is offset (shifted), with respect to the center position of the support members of the large substrate support member group (the first group), in either of the axial directions of the two axes. In other words, the large substrate support member group (the support members 10a, 10b, and 10c) and the small substrate support member group (the support members 12a, 12b, and 12c) are arranged such that the center position OS of the target object 300 is offset, with respect to the center position OL of the target object 101, in the x direction (an example of the direction of a moving axis) of the two directions of moving axes of the XY stage 106 and the Z stage 107. That is, each of the center positions of the large substrate support member group (the support members 10a, 10b, and 10c) and the small substrate support member group (the support members 12a, 12b, and 12c) is arranged such that one center position is offset, with respect to the other center position, in the x direction. In the cases of FIGS. 2 to 4, the center position OS of the target object 300 is offset to the position closer to the mark 212, with respect to the center position OL of the target object 101. The small substrate support member group (the support members 12a, 12b, and 12c) is arranged closer to the support member 10a at the mark 212 side compared with the center of the large substrate support member group (the support members 10a, 10b, and 10c) and in the range where the target object 300 does not contact with the support member 10a. During performing writing to the target object 101 or 300, a checking operation with respect to the beam position is performed a plurality of times to check whether the beam position on the surface of the target object has deviated or not due to a beam trajectory change in the electron optical column 102. At each checking time, the stage mechanism 105 is moved so that the mark 212 may be located in the range scannable with the multiple beams 20, for example, at the trajectory central axis of the multiple beams 20. By offsetting the center position OS of the target object 300 to the mark 212 side, the stage movement amount at the time of checking the beam position during writing to the target object 300 can be reduced.

The support members of the large substrate support member group are arranged to be symmetrical with respect to either of the two axial directions in which the Z stage 107 can be moved. Similarly, the support members of the small substrate support member group are arranged to be symmetrical with respect to either of the two axial directions in which the Z stage 107 can be moved. For example, the three or more support members 10a, 10b, and 10c of which the large substrate support member group is composed are arranged to be symmetrical with respect to the x-direction moving axis in two direction moving axes of the XY stage 106 and the Z stage 107. Similarly, the three or more support members 12a, 12b, and 12c of which the small substrate support member group is composed are arranged to be symmetrical with respect to the x-direction moving axis in two direction moving axes of the XY stage 106 and the Z stage 107. In the example of FIG. 2, the support members 10b and 10c are arranged to be symmetrical with respect to the x-direction moving axis which passes through the support member 10a. Similarly, the support members 12b and 12c are arranged to be symmetrical with respect to the x-direction moving axis which passes through the support member 12a arranged on the x-direction moving axis passing through the support member 10a. Thereby, it is difficult for the target objects 101 and 300 to slide on the support members when the stage mechanism 105 performs speed-up or speed-down on the x-direction moving axis.

The height position of the support member 10 is different from that of the support member 12. Therefore, the height position of the surface of the target object 101 supported by the support members 10a, 10b, and 10c is different from that of the target object 300 supported by the support members 12a, 12b, and 12c. The height position of the surface of the target object 300 is lower than that of the target object 101. Then, the Z stage 107 makes an adjustment so that both the height positions of the surfaces of the target objects 101 and 300 may be the height position of the surface of the mark 212.

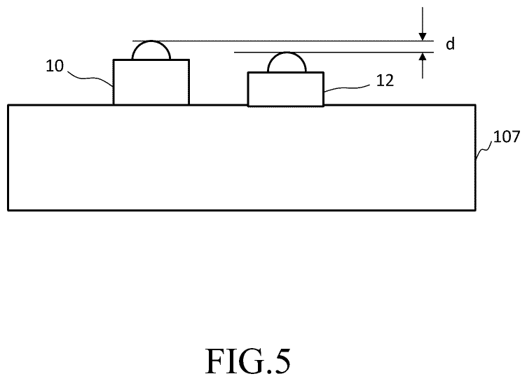

FIG. 5 is an illustration showing an example of a configuration of a support member according to the first embodiment. In FIG. 5, each of the support members 10 and 12 has a configuration where, on the upper part of the cylindrical structure, a hemisphere is arranged with its spherical surface facing upwards. Each of the target objects 101 and 300 is supported, at a point, by the upper end of the spherical surface of the hemisphere. The height positions of the support members 12a, 12b, and 12c are lower than those of the support members 10a, 10b, and 10c by the size (length) d which is larger (longer) than the deflection/flexure amount Δ of the target object 101 supported by the support members 10a, 10b, and 10c. As shown in FIG. 3, the height position of each of the support members 12a, 12b, and 12c is set such that, when the target object 101 is deflected (flexed) by the deflection/flexure amount Δ, there is a space s between each of the support members 12a, 12b, and 12c and the lower height position of the target object 101. It is preferable to set the size d to be, for example, 8 to 15μm with a margin considering adhesion of dust such as particles in the case that the deflection/flexure amount Δ of the target object is estimated to be 5 or less μm. For example, it is preferable to set the size d to be 10 μm.

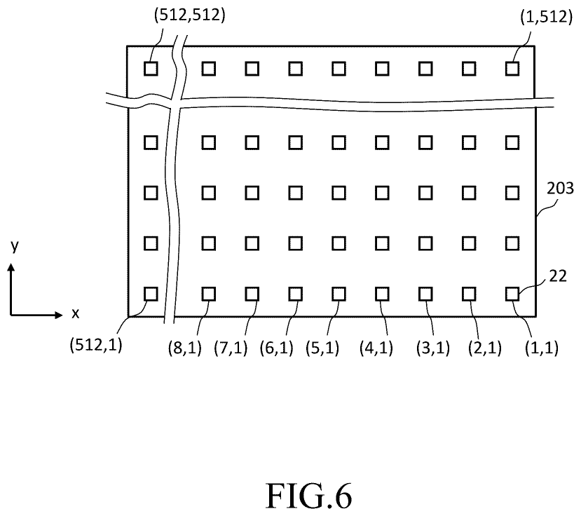

FIG. 6 is a conceptual diagram showing a configuration of a shaping aperture array substrate according to the first embodiment. As shown in FIG. 6, holes (openings) 22 of p columns wide (width in the x direction) and q rows long (length in the y direction) (p≥2, q≥2) are formed, like a matrix, at a predetermined array pitch in the shaping aperture array substrate 203. In the case of FIG. 6, for example, holes 22 of 512×512, that is 512 holes in the x direction and 512 holes in the y direction, are formed. The number of the holes 22 is not limited thereto. For example, it is also preferable to form the holes 22 of 32×32. Each of the holes 22 is a rectangle (including a square) having the same dimension and shape as each other. Alternatively, each of the holes 22 may be a circle with the same diameter as each other. Multiple beams 20 are formed by letting portions of an electron beam 200 individually pass through a corresponding one of a plurality of holes 22. In other words, the shaping aperture array substrate 203 forms and emits the multiple beams 20. The shaping aperture array substrate 203 serves as an example of an emission source of the multiple beams 20 or an example of a multiple beam forming mechanism.

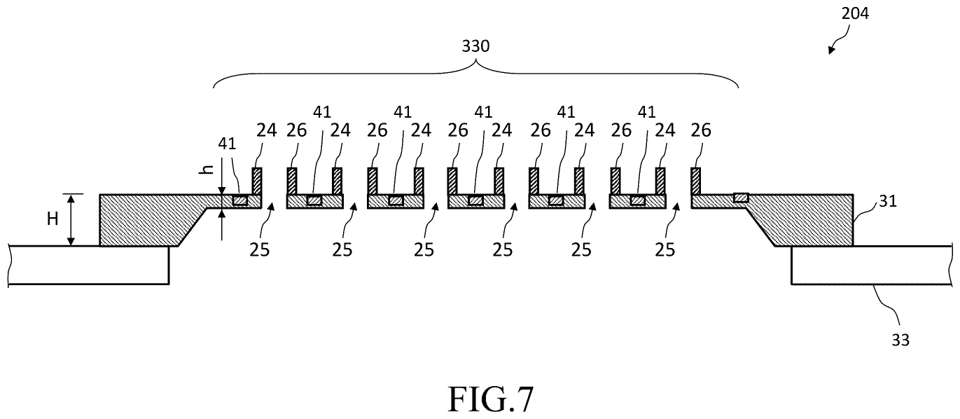

FIG. 7 is a sectional view showing a configuration of a blanking aperture array mechanism according to the first embodiment. In the blanking aperture array mechanism 204, as shown in FIG. 7, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 6. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. In a state where an L potential is applied to the input (IN) of the amplifier, the output (OUT) of the amplifier, which is to be applied to the control circuit 41, becomes a positive potential (Vdd), and then, a corresponding beam is deflected by an electric field due to a potential difference from the ground potential of the counter electrode 26, and is controlled to be in a beam-OFF condition by being blocked by the limiting aperture substrate 206. In contrast, in a state (active state) where an H potential is applied to the input (IN) of the amplifier, the output (OUT) of the amplifier becomes a ground potential, and therefore, since there is no potential difference from the ground potential of the counter electrode 26, a corresponding beam is not deflected, and is controlled to be in a beam-ON condition by passing through the limiting aperture substrate 206. Blanking control is provided by such deflection.

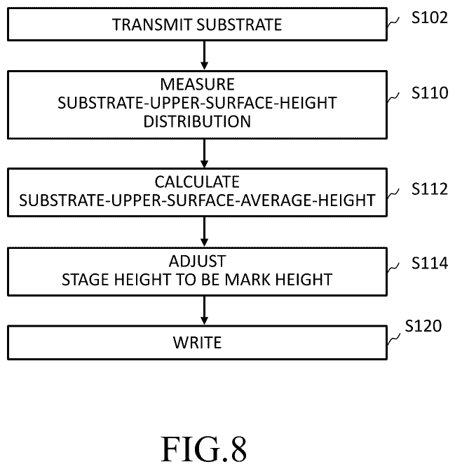

FIG. 8 is a flowchart showing an example of main steps of a writing method according to the first embodiment. In FIG. 8, the writing method of the first embodiment executes a series of steps: a substrate transmission step (S102), a substrate-upper-surface-height distribution measurement step (S110), a substrate-upper-surface-average-height calculation step (S112), a stage height adjustment step (S114), and a writing step (S120).

In the substrate transmission step (S102), using the writing apparatus 100 (charged particle beam irradiation apparatus) which includes the stage mechanism 105, one of the target objects 101 and 300 is placed on either the support members of the large substrate support member group composed of three or more support members including at least one support member 10, or the support members of the small substrate support member group composed of three or more support members including at least one support member 12. Specifically, under the control of the writing control unit 62, one of the target objects 101 and 300 is transmitted onto the stage mechanism 105 in the writing chamber 103, using a transmission robot (not shown). When transmitting the target object 101, being a large substrate, onto the stage mechanism 105, the target object 101 is placed on the three support members 10a, 10b and 10c. Thereby, the target object 101 is supported at three points by the three support members 10a, 10b, and 10c. When transmitting the target object 300, being a small substrate, onto the stage mechanism 105, the target object 300 is placed on the three support members 12a, 12b and 12c. Thereby, the target object 300 is supported at three points by the three support members 12a, 12b, and 12c.

In the substrate-upper-surface-height distribution measurement step (S110), under the control of the height measurement processing unit 50, the stage control mechanism 138 moves the stage mechanism 105 in order that a plurality of positions in each stripe region 32 may be individually located at an irradiation position of a laser beam emitted from the height position sensor 220. Then, under the control of the height measurement processing unit 50, the height position sensor 220 individually measures height positions of a plurality of positions in each stripe region 32 of the target object 101 (300). Information on measured height position is output to the control computer 110, together with position information on coordinates of portions measured by the stage position measuring instrument 139.

In the substrate-upper-surface-average-height calculation step (S112), the average height calculation unit 52 calculates an average height position of the upper surface of the target object 101 (300).

In the stage height adjustment step (S114), under the control of the height adjustment processing unit 54, the stage control mechanism 138 moves the Z stage 107 so that a calculated average height position may be coincident with the upper surface height position of the mark 212. The stage control mechanism 138 serves as an example of a height adjustment mechanism which adjusts the height of the Z stage 107.

In the writing step (S120), the electron optical column 102 (electron beam column) irradiates a supported (placed) target object 101 or a supported (placed) target object 300 with charged particle beams. Expressed in another way, using the multiple beams 20 (charged particle beams), the writing mechanism 150 individually writes a pattern on the target object 101 and the target object 300, which are supported at a different timing by the stage mechanism 105. For example, when the target object 101 is supported by the stage 105, a desired pattern is written on the target object 101. For example, when the target object 300 is supported by the stage 105, a desired pattern is written on the target object 300.

Operations of the writing mechanism 150 will be specifically described. The electron beam 200 emitted from the electron source 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam-on to becoming beam-off and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

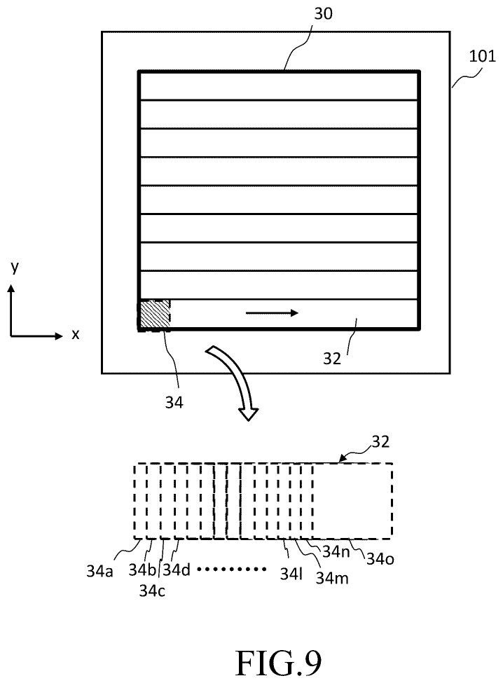

FIG. 9 is a conceptual diagram for explaining an example of a writing operation according to the first embodiment. As shown in FIG. 9, a writing region 30 (bold line) of the target object 101 is virtually divided into a plurality of stripe regions 32 by a predetermined width in the y direction, for example. In the case of FIG. 9, the writing region 30 of the target object 101 (300) is divided in the y direction, for example, into a plurality of stripe regions 32 by the width size being substantially the same as the design size of an irradiation region 34 (writing field) that can be irradiated with one irradiation of the multiple beams 20.

First, the XY stage 105 is moved to make an adjustment such that the irradiation region 34 of the multiple beams 20 is located at the left end, or at a position further left than the left end, of the first stripe region 32, and then, writing of the first stripe region 32 is performed. When writing the first stripe region 32, the XY stage 105 is moved, for example, in the-x direction, so that the writing may proceed relatively in the x direction. The XY stage 105 is moved, for example, continuously at a constant speed. After writing the first stripe region 32, the stage position is moved in the-y direction by the width of the stripe region 32.

Next, an adjustment is made so that the irradiation region 34 of the multiple beams 20 can be located at the left end, or at a position further left than the left end, of the second stripe region 32. Then, writing of the second stripe region 32 is performed by moving the XY stage 105, for example, in the −x direction to proceed the writing relatively in the x direction.

In the examples described above, respective stripe regions 32 are written in the same direction, but it is not limited thereto. For example, with respect to the stripe region 32 to be written following the stripe region 32 having been written in the x direction, it may be written in the-x direction by moving the XY stage 105 in the x direction, for example. Thus, due to performing writing while alternately changing the writing direction, the stage moving time can be reduced, which results in reducing the writing time. Owing to one shot of multiple beams having been formed by individually passing through the holes 22 in the shaping aperture array substrate 203, a plurality of shot patterns up to the number of the holes 22 are maximally formed at a time.

Although FIG. 9 shows the case where the stage moving for writing each stripe region is performed once for each writing, it is not limited thereto. It is also preferable to perform multiple writing (multiple pass writing) such that the stage moves on the same position a plurality of times. In that case, for example, in the case of N-time multiple pass writing, preferably, the multiple writing is performed while shifting the position in the y direction by 1/N of the width of the stripe region. Alternatively, it is also preferable to perform multiple writing (multiple writing in a pass) that writes the same position plural times by different beams during one stage movement.

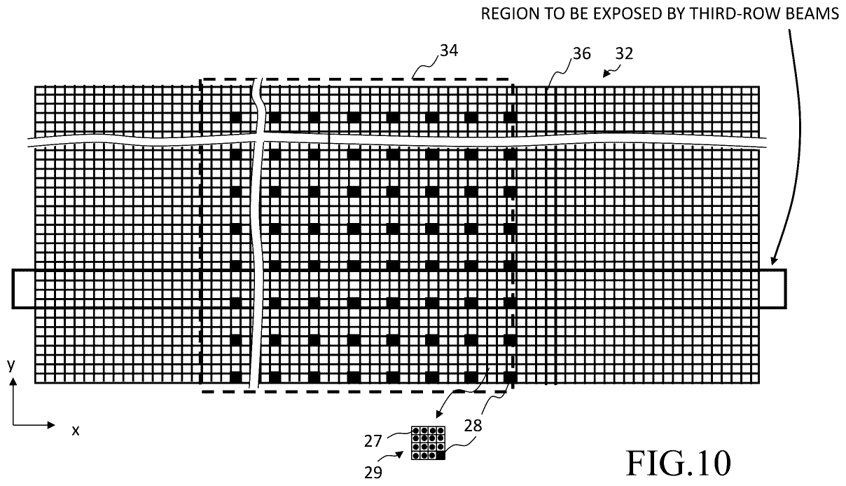

FIG. 10 is an illustration showing an example of an irradiation region of multiple beams and a pixel to be written (writing target pixel) according to the first embodiment. In FIG. 10, the stripe region 32 is divided into a plurality of mesh regions by the beam size of each of the multiple beams 20, for example. Each mesh region serves as a writing target pixel 36 (beam irradiation unit region, irradiation region). The center of each pixel 36 is a writing grid 27 serving as a coordinate to be irradiated with beams. The size of the writing target pixel 36 is not limited to the beam size, and may be any size regardless of beam size. For example, it may be 1/n (n being an integer of 1 or more) of the beam size. FIG. 10 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the design rectangular, including square, irradiation region 34 can be defined by (the number of x-direction beams)×(x-direction beam pitch). The y-direction size of the irradiation region 34 can be defined by (the number of y-direction beams)×(y-direction beam pitch). FIG. 10 shows the case of multiple beams of 512×512 (rows ×columns) having been simplified to 8×8 (rows ×columns). In the irradiation region 34, there are shown a plurality of pixels 28 (beam writing positions) which can be irradiated with one shot of the multiple beams 20. The pitch between adjacent pixels 28 is a beam pitch (pitch between beams) of the multiple beams. A sub-irradiation region 29 (pitch cell region) is configured by a rectangular, including square, region surrounded by the size of beam pitches in the x and y directions. In the example of FIG. 10, each sub-irradiation region 29 is composed of 4×4 pixels, for example.

Now, a writing operation sequence will be described. FIG. 10 shows the case where the inside of each sub-irradiation region 29 is written with four different beams, for example. During a ¼ region, namely the region of 1/(the number of beams used for irradiation), in each sub-irradiation region 29 being written, the XY stage 105 continuously moves at the speed at which it moves the distance of eight beam pitches, for example. FIG. 10 shows the case where each sub-irradiation region 29 is composed of 4×4 pixels, for example. In the writing operation shown in FIG. 10, for example, while the XY stage 105 moves the distance of eight beam pitches, four different pixels 36 in the same sub-irradiation region 29 are written (exposed) by applying four shots of the multiple beams 20 at a shot cycle T with sequentially shifting the irradiation position (pixel 36) by the sub deflector 209. In order that the relative position between the irradiation region 34 and the substrate 101 may not be displaced by the movement of the XY stage 105 while the four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking start position. Since writing of the pixels in the first column from the right of each sub-irradiation region 29 has been completed, in the next tracking cycle after resetting the tracking, first, the sub deflector 209 provides deflection such that the writing position of a beam is adjusted (shifted) to write the second pixel column from the right which has not yet been written in each sub-irradiation region 29, for example. By repeating this operation during performing writing in the stripe region 32, as shown in the lower part of FIG. 9, the position of the irradiation region 34 (34a to 34o) of the multiple beams 20 is sequentially moved (shifted) to perform writing.

As described above, according to the first embodiment, a plurality of target objects 101 and 300 of different sizes can be placed/arranged by the stage mechanism 105.

### Second Embodiment

In the first embodiment described above, the long side direction of the rectangular target object 101 is set to be in the writing direction (x direction), but it is not limited thereto. According to a second embodiment, the long side direction of the rectangular target object 101 is set to be in the y direction orthogonal to the writing direction (x direction). The contents of the second embodiment are the same as those of the first embodiment except for what is particularly described below.

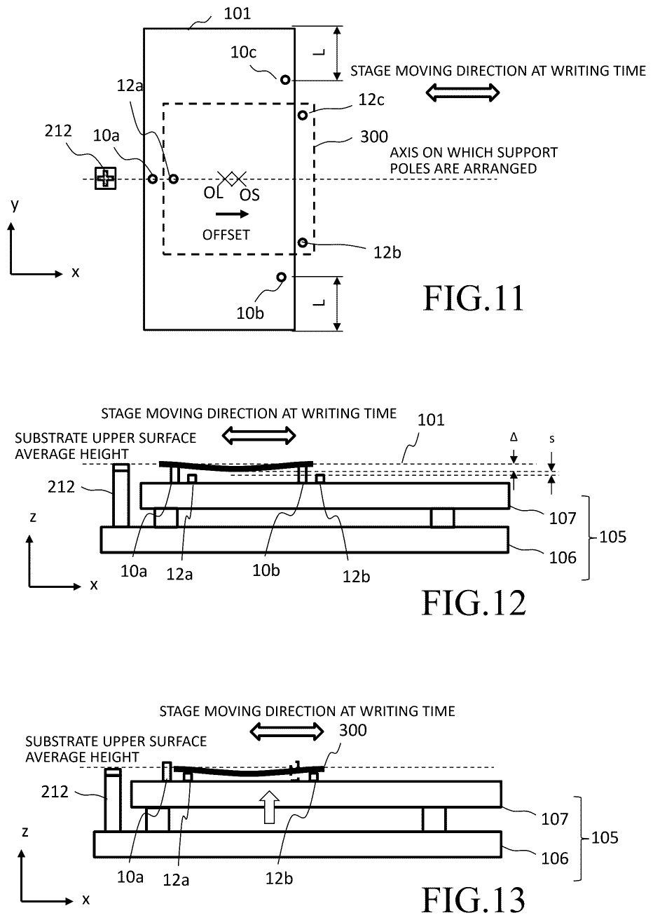

FIG. 11 is a top view showing an example of arrangement position of a plurality kinds of target objects arranged on a stage mechanism according to the second embodiment.

FIG. 12 is a front view showing an example of a configuration of a stage mechanism in the state where an example of a target object is placed on the stage mechanism according to the second embodiment.

FIG. 13 is a front view showing an example of a configuration of a stage mechanism in the state where another example of a target object is placed on the stage mechanism according to the second embodiment.

In the case of FIG. 11, similarly to the first embodiment, for example, a 6×12 inch mask substrate is used as the target object 101, and a 6×6 inch mask substrate is used as the target object 300. On the Z stage 107, there are arranged three or more support members 10 (support pins) (the first support member), which are placed on the same height position, and at least one support member 12 (support pin) (the second support member), whose height position is lower than that of the support member 10. In the cases of FIGS. 11 to 13, three support members 10 (10a, 10b, 10c) and three support members 12 (12a, 12b, 12c) are disposed.

The large target object 101 is supported by three or more support members 10a, 10b, and 10c, of which the large substrate support member group (the first group) is composed, in a plurality of support members 10. In the cases of FIGS. 11 to 13, the target object 101 is supported at three points by the three support members 10a, 10b, and 10c in the state where the long side direction of the rectangular target object 101 is set to be in the y direction orthogonal to the writing direction (x direction).

Each of the support members 10a, 10b, and 10c is disposed close to the end of the target object 101. However, if the x-direction size and the y-direction size of the target object 101 are different from each other, the support member 10a is arranged at the intermediate position of the long side of the target object 101 and close to one end of the short side of the target object 101. The other two support members 10b and 10c are arranged close to the other end of the short side of the target object 101 and at the positions inner from the end of the long side of the target object 101 by a length L. As the length L, similarly to the first embodiment, ⅓ or less of the length of the long side is set. More preferably, the length L is set to be in the range from ⅓ to ⅕ of the length of the long side of the target object 101. By arranging the three support members 10a, 10b, and 10c at the positions described above, deflection/flexure of the target object 101 at the time of being supported at the three points can be reduced.

In the cases of FIGS. 11 to 13, the support member 10a is arranged at the mark 212 side compared with the other two support members 10b and 10c, in terms of the axis in the x direction. However, it is not limited thereto. For example, the support member 10a may be arranged at the opposite side of the mark 212 side compared with the other two support members 10b and 10c, in terms of the axis in the x direction. In other words, the two support members 10b and 10c may be arranged at the mark 212 side compared with the other support member 10a, in terms of the axis in the x direction.

The small target object 300 is supported by three or more support members 12 of which the small substrate support member group (the second group) is composed. In the cases of FIGS. 11 to 13, the target object 300 is supported at three points by the three support members 12a, 12b, and 12c. Each of the support members 10a, 10b, and 10c that support the target object 300 whose x-direction size and y-direction size are the same is disposed close to the end of the target object 300. The support member 12a is arranged displaced in the x direction compared with the support member 10a. The support member 12b, and 12c are arranged between the support members 10b and 10c in the y direction, and displaced in the x direction compared with the support members 10b and 10c. Thereby, it is possible for the three support members 12a, 12b, and 12c not to interfere with the support member 10 when they support the small target object 300.

The large substrate support member group (the support members 10a, 10b, and 10c) and the small substrate support member group (the support members 12a, 12b, and 12c) are arranged such that the center position OS of the target object 300 is offset, with respect to the center position OL of the target object 101, in the x direction (an example of the direction of a moving axis) of the two directions of moving axes of the XY stage 106 and the Z stage 107. That is, each of the center positions of the large substrate support member group (the support members 10a, 10b, and 10c) and the small substrate support member group (the support members 12a, 12b, and 12c) is arranged offset in the x direction. In the cases of FIGS. 11 to 13, the center position OS of the target object 300 is offset, with respect to the center position OL of the target object 101, to the position away from the mark 212 compared with the center position OL. The support member 12a is arranged closer to the mark 212 side as long as the target object 300 does not contact with the support member 10a. By arranging the support member 12a closer to the mark side, the stage movement amount at the time of checking the beam position during performing writing to the target object 300 can be reduced.

The three or more support members 10a, 10b, and 10c, of which the large substrate support member group is composed, are arranged to be symmetrical with respect to the x-direction moving axis in two direction moving axes of the XY stage 106 and the Z stage 107. Similarly, the three or more support members 12a, 12b, and 12c, of which the small substrate support member group is composed, are arranged to be symmetrical with respect to the x-direction moving axis in two direction moving axes of the XY stage 106 and the Z stage 107. In the example of FIG. 11, the support members 10b and 10c are arranged to be symmetrical with respect to the x-direction moving axis which passes through the support member 10a. Similarly, the support members 12b and 12c are arranged to be symmetrical with respect to the x-direction moving axis which passes through the support member 12a arranged on the x-direction moving axis passing through the support member 10a. Thereby, it is difficult for the target objects 101 and 300 to slide on the support members when the stage mechanism 105 performs speed-up or speed-down on the x-direction moving axis.

Similarly to the first embodiment, the height position of the surface of the target object 300 supported by the support members 12a, 12b, and 12c is lower than the height position of the surface of the target object 101 supported by the support members 10a, 10b, and 10c. Then, the Z stage 107 makes an adjustment so that both the height positions of the surfaces of the target objects 101 and 300 may be the height position of the surface of the mark 212.

The other contents are the same as those in the first embodiment.

As described above, according to the second embodiment, even in the case where the long side direction of the rectangular target object 101 is set to be in the y direction orthogonal to the writing direction (x direction), a plurality of target objects 101 and 300 of different sizes can be placed/arranged by the stage mechanism 105.

### Third Embodiment

In each of the Embodiments described above, the support member 10 which supports the target object 101 and the support member 12 which supports the target object 300 are different from each other, but it is not limited thereto. A third embodiment describes the case where some of the three support members supporting the target object 101 and those supporting the target object 300 are used in common. The contents of the third embodiment are the same as those of the first or second embodiment except for what is particularly described below.

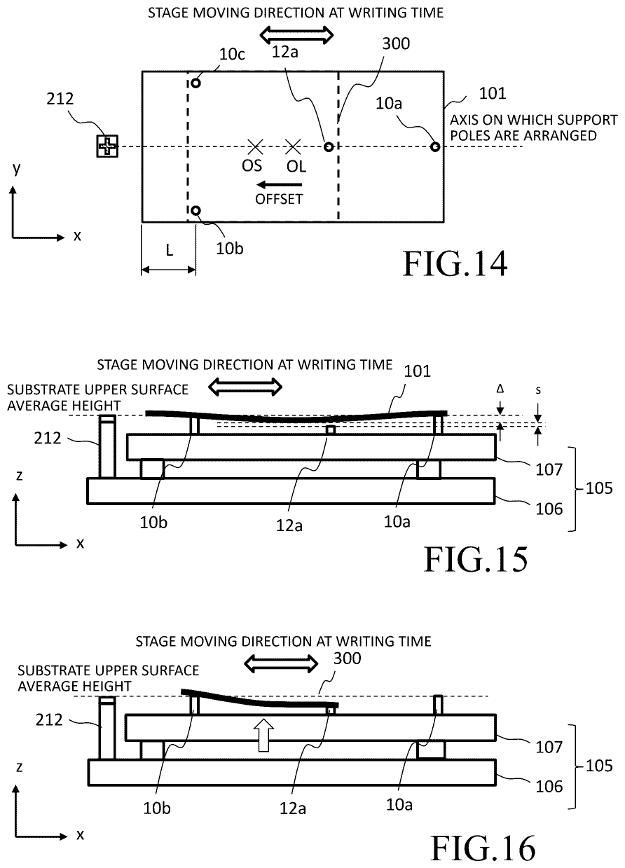

FIG. 14 is a top view showing an example of arrangement position of a plurality kinds of target objects arranged on a stage mechanism according to the third embodiment.

FIG. 15 is a front view showing an example of a configuration of a stage mechanism in the state where an example of a target object is placed on the stage mechanism according to the third embodiment.

FIG. 16 is a front view showing an example of a configuration of a stage mechanism in the state where another example of a target object is placed on the stage mechanism according to the third embodiment.

In the case of FIG. 14, similarly to the first embodiment, for example, a 6×12 inch mask substrate is used as the target object 101, and a 6×6 inch mask substrate is used as the target object 300. On the Z stage 107, there are arranged three or more support members 10 (support pins) (the first support member), which are placed on the same height position, and at least one support member 12 (support pin) (the second support member), whose height position is lower than that of the support member 10. In the cases of FIGS. 14 to 16, three support members 10 (10a, 10b, 10c) and one support member 12 (12a) are disposed.

According to the third embodiment, a common support member is included in the large substrate support member group (the first group) and the small substrate support member group (another example of the second group). It will be described in detail.

The large target object 101 is supported by the three or more support members 10a, 10b, and 10c, of which the large substrate support member group (the first group) is composed, in a plurality of support members 10. In the cases of FIGS. 14 to 16, the target object 101 is supported at three points by the three support members 10a, 10b, and 10c in the state where the long side direction of the rectangular target object 101 is set to be in the writing direction (x direction).

Each of the support members 10a, 10b, and 10c is disposed close to the end of the target object 101. However, if the x-direction size and the y-direction size of the target object 101 are different from each other, the support member 10a is arranged at the intermediate position of the short side of the target object 101, and close to one end of the long side of the target object 101, which is at the opposite side of the mark 212. The other two support members 10b and 10c are arranged close to the both ends of the short side of the target object 101, and at the positions inner by a length L from the end of the long side of the target object 101, which is at the mark 212 side. As the length L, similarly to the first embodiment, ⅓ or less of the length of the long side is set. More preferably, the length L is set to be in the range from ⅓ to ⅕ of the length of the long side of the target object 101. By arranging the three support members 10a, 10b, and 10c at the positions described above, deflection/flexure of the target object 101 at the time of being supported at the three points can be reduced.

In the cases of FIGS. 14 to 16, the support member 10a is arranged at the opposite side of the mark 212 compared with the other two support members 10b and 10c, in terms of the axis in the x direction,. However, it is not limited thereto. For example, the support member 10a may be arranged at the mark 212 side compared with the other two support members 10b and 10c, in terms of the axis in the x direction. In other words, the two support members 10b and 10c may be arranged at the opposite side of the mark 212 compared with the other support member 10a, in terms of the axis in the x direction.

The small target object 300 is supported by three or more support members 10b, 10c, and 12a being mixed members of the support member 10 and the support member 12, of which the small substrate support member group (another example of the second group) is composed. In the cases of FIGS. 14 to 16, the target object 300 is supported at three points by the three support members 10b, 10c, and 12a. Each of the support members 10b, 10c, and 12a that support the target object 300 whose x-direction size and y-direction size are the same is disposed close to the end of the target object 300. The support member 12a is arranged displaced in the-x direction compared with the support member 10a, and the support members 10b and 10c are used in common. Thereby, it is possible not to interfere with the support member 10a when supporting the small target object 300 by the three support members 10b, 10c, and 12a.

The large substrate support member group (the support members 10a, 10b, and 10c) and the small substrate support member group (the support members 12a, 10b, and 10c) are arranged such that the center position OS of the target object 300 is offset, with respect to the center position OL of the target object 101, in the x direction (an example of the direction of a moving axis) of the two directions of moving axes of the XY stage 106 and the Z stage 107. That is, each of the center positions of the large substrate support member group (the support members 10a, 10b, and 10c) and the small substrate support member group (the support members 12a, 10b, and 10c) is arranged offset in the x direction. In the cases of FIGS. 14 to 16, the center position OS of the target object 300 is offset, with respect to the center position OL of the target object 101, to the position at the mark 212 side. By commonly using the support members 10b and 10c at the mark 212 side, the stage movement amount at the time of checking the beam position during writing to the target object 300 can be reduced.

The three or more support members 10a, 10b, and 10c, of which the large substrate support member group is composed, are arranged to be symmetrical with respect to the x-direction moving axis in two direction moving axes of the XY stage 106 and the Z stage 107. Similarly, the three or more support members 12a, 10b, and 10c, of which the small substrate support member group is composed, are arranged to be symmetrical with respect to the x-direction moving axis in two direction moving axes of the XY stage 106 and the Z stage 107. In the example of FIG. 14, the support members 10b and 10c are arranged to be symmetrical with respect to the x-direction moving axis which passes through the support member 10a. The support member 12a is arranged on the x-direction moving axis which passes through the support member 10a. Thereby, it is difficult for the target objects 101 and 300 to slide on the support members when the stage mechanism 105 performs speed-up or speed-down on the x-direction moving axis.

Furthermore, in the third embodiment, the target object 101 supported by the support members 10a, 10b, and 10c whose heights are the same can be maintained to be level. In contrast, as shown in FIG. 16, since the target object 300 is supported by the support members 10b and 10c whose heights are higher and the support member 10a whose height is lower, it is arranged aslant. As described above, the height difference between the high support members 10b and 10c and the low support member 10a is about 10 μm. Then, according to the third embodiment, the focus deviation occurring in the target object 300 arranged aslant is corrected, based on dynamic focusing of the multiple beams 20, by applying a beam to a position whose height position deviation has been corrected by adjusting a focal height during writing. Preferably, the dynamic focusing is performed by an electrostatic lens (not shown). However, it is not excluded to perform dynamic focusing by using the objective lens 207.

The other contents are the same as those in the first embodiment.

As described above, according to the third embodiment, even in the case where the long side direction of the rectangular target object 101 is set to be in the y direction orthogonal to the writing direction (x direction) and some of the support members are used in common, a plurality of target objects 101 and 300 of different sizes can be placed/arranged by the stage mechanism 105.

### Fourth Embodiment

In the third embodiment described above, writing is performed in the state where the substrate 300 is arranged aslant. A fourth embodiment describes a configuration to move a slanting substrate 300 to be level. The contents of the fourth embodiment are the same as those of any one of the first to third embodiments except for what is particularly described below.

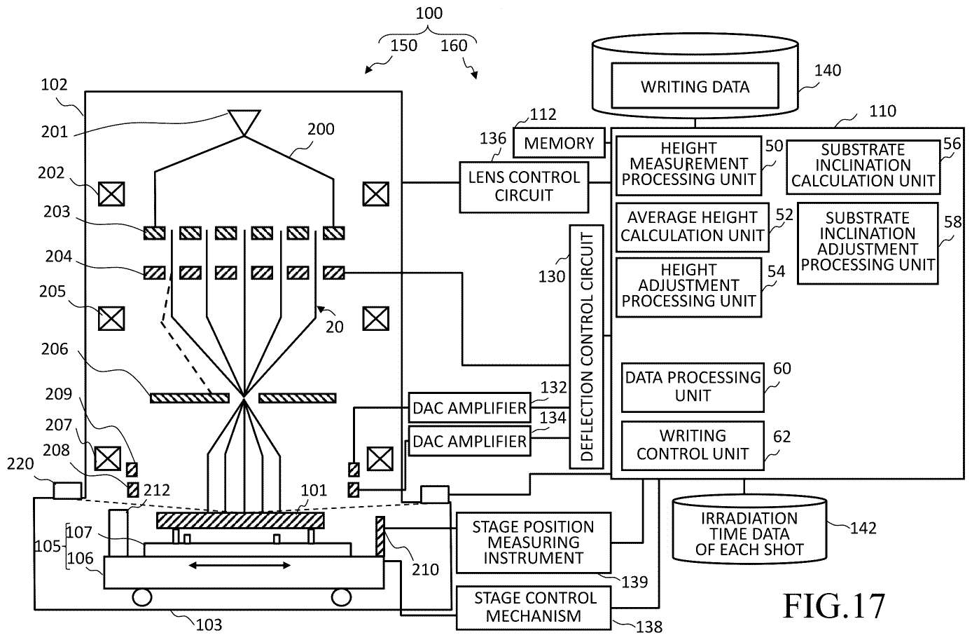

FIG. 17 is a conceptual diagram showing an example of a configuration of a writing apparatus according to the fourth embodiment. FIG. 17 is the same as FIG. 1 except that a substrate inclination calculation unit 56 and a substrate inclination adjustment processing unit 58 are further added in the control computer 110.

Each of the “ . . . units” such as the height measurement processing unit 50, the average height calculation unit 52, the height adjustment processing unit 54, the substrate inclination calculation unit 56, the substrate inclination adjustment processing unit 58, the data processing unit 60, and the writing control unit 62 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the height measurement processing unit 50, the average height calculation unit 52, the height adjustment processing unit 54, the substrate inclination calculation unit 56, the substrate inclination adjustment processing unit 58, the data processing unit 60, and the writing control unit 62, and information being operated are stored in the memory 112 each time.

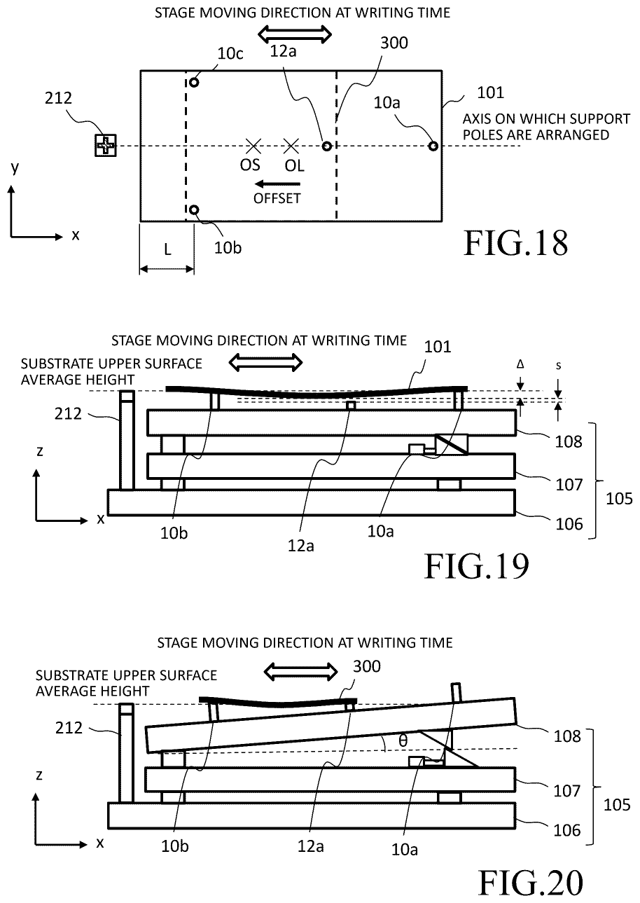

FIG. 18 is a top view showing an example of arrangement position of a plurality kinds of target objects arranged on a stage mechanism according to the fourth embodiment.

FIG. 19 is a front view showing an example of a configuration of a stage mechanism in the state where an example of a target object is placed on the stage mechanism according to the fourth embodiment.

FIG. 20 is a front view showing an example of a configuration of a stage mechanism in the state where another example of a target object is placed on the stage mechanism according to the fourth embodiment.

The stage mechanism 105 further includes at least one of an inclination adjustment mechanism which adjusts an inclination (gradient) of the stage, and a height adjustment mechanism which adjusts the height of the Z stage 107. For example, the stage mechanism 105 in the cases of FIGS. 18 to 20, an angle adjustment stage 108 (an example of an inclination adjustment mechanism) is arranged on the Z stage 107. The angle adjustment stage 108 adjusts inclination of the stage on which support members are arranged. On the angle adjustment stage 108, there are arranged three or more support members 10 (support pins) (the first support member), which are placed on the same height position, and at least one support member 12 (support pin) (the second support member), whose height position is lower than that of the support member 10. In the cases of FIGS. 18 to 20, three support members 10 (10a, 10b, 10c) and one support member 12 (12a) are disposed. The other contents are the same as those in the examples of FIGS. 14 to 16.

The angle adjustment stage 108 is arranged so that, for example, an angle θx in the x direction can be adjusted. For example, the angle adjustment stage 108 is configured where a tapered-shaped sliding mechanism is arranged at the stage's at least one end in the x direction, and the tapered-shaped sliding mechanism is moved in the x direction by driving a piezoelectric element etc. By this, the one end in the x direction of the angle adjustment stage 108 is lifted by the tapered portion in order to variably adjust the angle of the upper surface of the angle adjustment stage 108. However, it is not limited thereto. It is also preferable to have a configuration where both the angle θx in the x direction and the angle θy in the y direction can be adjusted. The sliding mechanism and the piezoelectric element serve as examples of a height adjustment mechanism for adjusting the height of the Z stage 107.

As described above, the target object 101 supported by the support members 10a, 10b, and 10c whose heights are the same can be maintained to be level. In contrast, as shown in FIG. 16, since the target object 300 is supported by the support members 10b and 10c whose heights are higher and the support member 10a whose height is lower, it is arranged aslant. Then, according to the fourth embodiment, the angle adjustment stage 108 eliminates the inclination of the target object 300 and maintains it to be level.

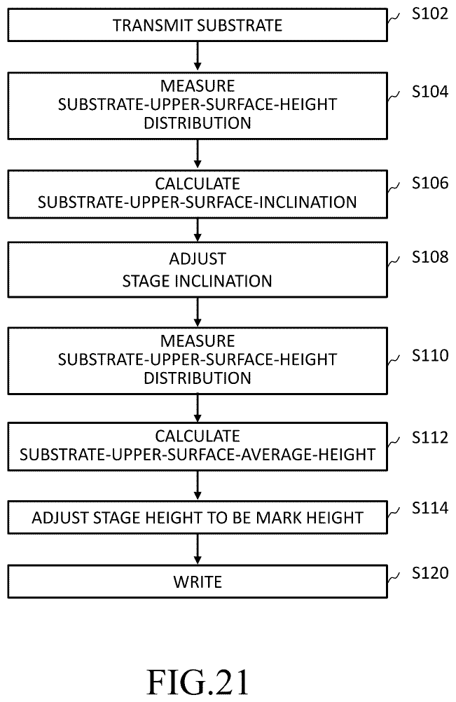

FIG. 21 is a flowchart showing an example of main steps of a writing method according to the fourth embodiment. In FIG. 21, between the substrate transmission step (S102) and the substrate-upper-surface-height distribution measurement step (S110), a substrate-upper-surface-height distribution measurement step (S104), a substrate-upper-surface-inclination calculation step (S106), and a stage inclination adjustment step (S108) are carried out.

The contents of the substrate transmission step (S102) are the same as those of the first embodiment.

In the substrate-upper-surface-height distribution measurement step (S104), under the control of the height measurement processing unit 50, the stage control mechanism 138 moves, in order, the stage mechanism 105 so that three or more points of the substrate 300 (101), being apart from each other, may be located on positions of a laser beam emitted from the height position sensor 220. Then, under the control of the height measurement processing unit 50, the height position sensor 220 individually measures the height position of each of the mutually parted three or more points of the target object 300 (101). Information on the measured height position is output to the control computer 110, together with position information on coordinates of measurement points measured by the stage position measuring instrument 139.

In the substrate-upper-surface-inclination calculation step (S106), using information on the measured height position of each of mutually parted three or more points, the substrate inclination calculation unit 56 calculates an inclination of the target object 300 (101). For example, θx being an inclination in the x direction and θy being an inclination in the y direction are calculated. If there are three of more calculated points, the arrangement position of the target object can be determined, and therefore, inclination of the target object 300 (101) can be calculated. For example, an x-direction inclination θx can be calculated by differentiating height positions of two or more points in the x direction.

In the stage inclination adjustment step (S108), under the control of the substrate inclination adjustment processing unit 58, the stage control mechanism 138 moves the angle adjustment stage 108 so that a calculated inclination angle can become zero. Thereby, as shown in FIG. 20, in the case where the target object 300 is supported by the support members 10b and 10c whose heights are higher and the support member 10a whose height is lower, the target object 300 can be maintained to be level. It is also preferable to similarly adjust the target object 101.

The contents in and after the substrate-upper-surface-height distribution measurement step (S110) are the same as those of the first embodiment.

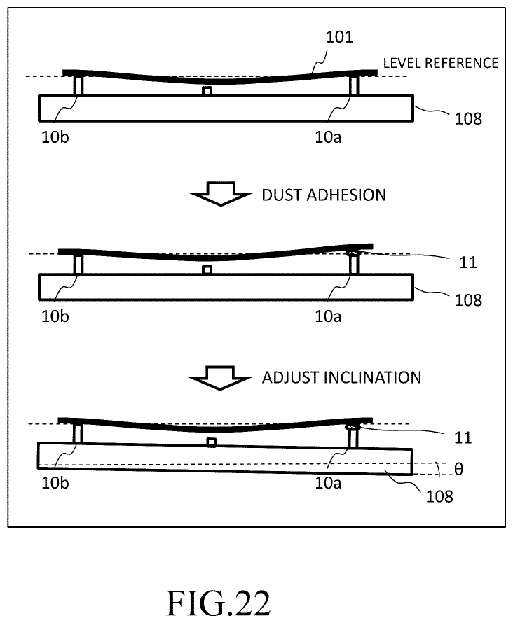

FIG. 22 is an illustration explaining an example of another usage method of an angle adjustment stage according to the fourth embodiment. As shown in the upper part of FIG. 22, the target object 101 supported by the support members 10a, 10b, and 10c whose heights are the same can be ideally maintained to be level. However, if the target object 101 is supported in the state where the upper surface of any one of the support members 10a, 10b, and 10c is with dust such as particles, the target object 101 becomes inclined as shown in the middle part of FIG. 22. In that case, as shown in the lower part of FIG. 22, by carrying out the substrate-upper-surface-height distribution measurement step (S104), the substrate-upper-surface-inclination calculation step (S106), and the stage inclination adjustment step (S108) described above, the target object 101 can be adjusted to be level even in the state of being adhered with dust.

As described above, according to the fourth embodiment, a plurality of target objects 101 and 300 of different sizes can be arranged/placed to be level by the stage mechanism 105 even when the target objects are supported by a plurality of support members of different heights.

### Fifth Embodiment

Each of the above Embodiments describes the stage mechanism 105 which supports two kinds of target objects having different sizes from each other. A fifth embodiment describes the stage mechanism 105 which supports three or more kinds of target objects having different sizes from each other. The contents of the fifth embodiment are the same as those of any one of the first to fourth embodiments except for what is particularly described below.

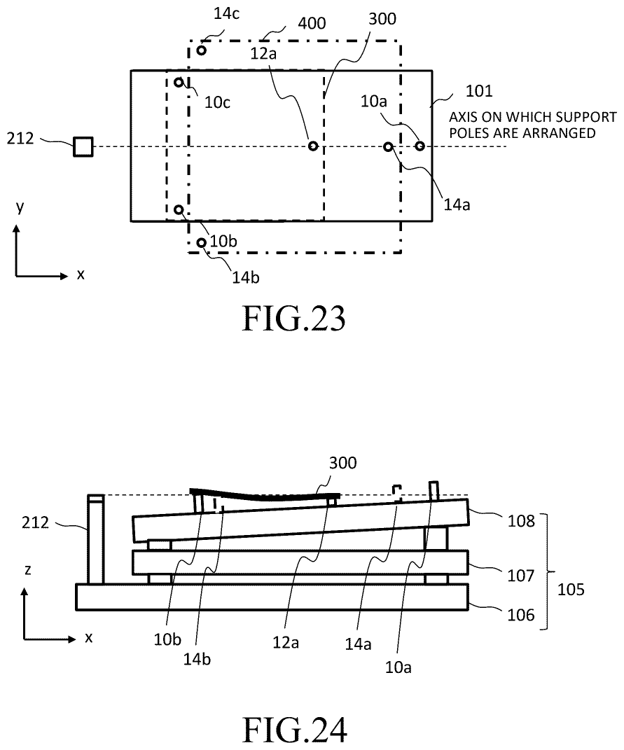

FIG. 23 is a top view showing an example of arrangement position of a plurality kinds of target objects arranged on a stage mechanism according to the fifth embodiment.

FIG. 24 is a front view showing an example of a configuration of a stage mechanism in the state where an example of a target object is placed on the stage mechanism according to the fifth embodiment.

In the stage mechanism 105 of the cases of FIGS. 23 and 24, the angle adjustment stage 108 is arranged on the Z stage 107. Then, on the angle adjustment stage 108, there arranged three or more support members 10 (support pins) (the first support member), which are placed on the same height position, at least one support member 12 (support pin) (the second support member), whose height position is lower than that of the support member 10, and at least one support member 14 (support pin) (the third support member), whose height position is lower than that of the support member 10 and higher than that of the support member 12. In the cases of FIGS. 23 and 24, three support members 10 (10a, 10b, 10c), one support member 12 (12a), and three support members 14 (14a, 14b, 14c) are disposed. The other contents are the same as those in the examples of FIGS. 18 to 20.

The angle adjustment stage 108 is arranged so that, for example, an angle θx in the x direction can be adjusted.

In the case of FIG. 23, similarly to the first embodiment, a 6×12 inch mask substrate is used as the target object 101, and a 6×6 inch mask substrate is used as the target object 300, for example. Furthermore, a 9×9 inch mask substrate is used as a target object 400, for example.

According to the fifth embodiment, a common support member is included in the large substrate support member group (the first group) and the small substrate support member group (another example of the second group). It will be described in detail.

The large target object 101 is supported by the three or more support members 10a, 10b, and 10c, of which the large substrate support member group (the first group) is composed, in a plurality of support members 10. In the cases of FIGS. 23 and 24, the target object 101 is supported at three points by the three support members 10a, 10b, and 10c in the state where the long side direction of the rectangular target object 101 is set to be in the writing direction (x direction). The positional relationship among the support members 10a, 10b, and 10c is the same as that of the third embodiment.

The small target object 300 is supported by three or more support members 10b, 10c, and 12a being mixed members of the support member 10 and the support member 12, of which the small substrate support member group (another example of the second group) is composed. The positional relationship among the support members 10b, 10c, and 12a is the same as that of the third embodiment.

Furthermore, according to the fifth embodiment, an intermediate-sized target object 400 is supported by three or more support members 14a, 14b, and 14c, of which an intermediate-sized substrate support member group (the third group) is composed, in a plurality of support members 14. In the cases of FIGS. 23 and 24, the target object 400 whose x-direction size and y-direction size are the same is supported at three points by the three support members 14a, 14b, and 14c. Each of the support members 14a, 14b, and 14c which support the target object 400 is disposed close to the end of the target object 400. The three support members 14a, 14b, and 14c are arranged within the range between the support member 10a and the support members 10b and 10c with respect to the long side direction (the x direction) of the target object 101. Thereby, it is possible for the three support members 14a, 14b, and 14c not to interfere with the support member 10 when they support the target object 400 having an intermediate size between the target objects 101 and 300. The support member 14a is arranged between the support member 10a and the support member 12a, on the x-direction moving axis passing through the support member 10a. The support member 14b is arranged, outside the target object 101 with respect to the y direction compared with the support member 10b, on the position where the target object 400 does not interfere with the support members 10b and 10c with respect to the x direction. The support member 14c is arranged, outside the target object 101 with respect to the-y direction compared with the support member 10c, on the position where the target object 400 does not interfere with the support members 10b and 10c with respect to the x direction.

The three or more support members 14a, 14b, and 14c of which the intermediate-sized substrate support member group is composed, are arranged to be symmetrical with respect to the x-direction moving axis which passes through the support member 10a. Thereby, it is difficult for the target object 400 to slide on the support members when the stage mechanism 105 performs speed-up or speed-down on the x-direction moving axis.

Although FIGS. 23 and 24 show the case where the three kinds of target objects 101, 300 and 400 of different sizes can be placed on the stage mechanism 105, it is also acceptable that four or more kinds of target objects of different sizes are similarly placed.

Thus, as described above, according to the fifth embodiment, the three or more kinds of target objects 101, 300, and 400 of different sizes can be arranged.

Embodiments have been explained referring to specific examples described above. However, embodiments of the present invention are not limited to these specific examples. Functions of the processing described in the above embodiments may be executed by a computer. A program for causing a computer to implement such functions of processing may be stored in a non-transitory tangible computer-readable storage medium such as a magnetic disk drive. Furthermore, embodiments of the present invention are not limited to writing, but also to alignment. Thus, it can be used for a charged particle beam irradiation apparatus in addition to a writing apparatus such as an inspection apparatus.

While the apparatus configuration, control method, and others not directly necessary for explaining the present invention are not described, some or all of them can be appropriately selected and used on a case-by-case basis when needed. For example, in also other embodiments, as well as the third embodiment, focus adjustment may be performed by dynamic focusing, based on a height distribution of a target object surface.

Any stage mechanism, charged particle beam irradiation apparatus, and charged particle beam irradiation method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A stage mechanism comprising:
a stage configured to be movable; and
four or more support members configured to include a first support member whose upper end is arranged at a first height, and a second support member whose upper end is arranged at a second height lower than the first height, to be arranged such that height positions of upper ends of the four or more support members are between at least the second height and at most the first height, where the first height and the second height are included, and to be fixed on the stage, wherein
the stage mechanism can individually selectively support a plurality of substrates having different sizes, and
any one of the plurality of substrates is supported by either one of by respective upper ends of support members of a first group which is composed of three or more support members including the first support member in the four or more support members, and by respective upper ends of support members of a second group which is composed of three or more support members including the second support member in the four or more support members.

2. The stage mechanism according to claim 1, wherein
the first group and the second group include a common support member.

3. The stage mechanism according to claim 1, wherein
the stage is movable in two axial directions in a same plane, and
the support members of the first group and the support members of the second group are arranged such that, with respect to a center position of the support members of the first group, a center position of the support members of the second group is arranged to be offset in either of the two axial directions.

4. The stage mechanism according to claim 1, wherein
the stage is movable in two axial directions in a same plane, and
the support members of the first group and the support members of the second group are individually arranged to be symmetrical with respect to either of the two axial directions.

5. The stage mechanism according to claim 1 further comprising:
at least one of an inclination adjustment mechanism configured to adjust an inclination of the stage, and a height adjustment mechanism configured to adjust a height of the stage.

6. The stage mechanism according to claim 1, wherein
the first height and the second height are determined based on a flexure amount of a substrate, placed on the support members of the first group, in the plurality of substrates having different sizes.

7. A charged particle beam irradiation apparatus comprising:
a stage mechanism configured to include
a stage which is movable, and
four or more support members which include a first support member whose upper end is arranged at a first height, and a second support member whose upper end is arranged at a second height lower than the first height, which are arranged such that height positions of upper ends of the four or more support members are between at least the second height and at most the first height, where the first height and the second height are included, and which are fixed on the stage, wherein
the stage mechanism can individually selectively support a plurality of substrates having different sizes, and
any one of the plurality of substrates is supported by either one of by respective upper ends of support members of a first group which is composed of three or more support members including the first support member in the four or more support members, and by respective upper ends of support members of a second group which is composed of three or more support members including the second support member in the four or more support members; and
an irradiation mechanism configured to irradiate the any one of the plurality of substrates supported with a charged particle beam.

8. A charged particle beam irradiation method comprising:
placing any one of a plurality of substrates, by using a charged particle beam irradiation apparatus that includes a stage mechanism which includes a stage being movable, and four or more support members where a first support member whose upper end is arranged at a first height and a second support member whose upper end is arranged at a second height lower than the first height, wherein the four or more support members are arranged such that height positions of upper ends of the four or more support members are between at least the second height and at most the first height, including the first height and the second height, and are fixed on the stage, wherein the stage mechanism can individually selectively support a plurality of substrates having different sizes, on either one of on respective upper ends of support members of a first group which is composed of three or more support members including the first support member in the four or more support members, and on respective upper ends of support members of a second group which is composed of three or more support members including the second support member in the four or more support members; and
irradiating the any one of the plurality of substrates placed with a charged particle beam.
